(19) United States
(12) Patent Application Publication
(10) Pub. No.: US 2003/0045112 A1
(43) Pub. Date: Mar. 6, 2003

(54) Ion implantation to induce selective etching

(76) Inventors: Raymond Jeffrey Vass, Greensboro, NC (US); Scott I. Hill, Thomasville, NC (US)

Correspondence Address: WITHROW & TERRANOVA, P.L.L.C., P.O. BOX 1287, CARY, NC, 27512, US

(21) Appl. No.: 09/945,183

(22) Filed: Aug. 31, 2001

(51) Int. Cl. H01L 21/302; H01L 21/461

(52) U.S. Cl. 438/705

(57) ABSTRACT

The present invention is an improved method for etching away portions of epitaxial layers in a multi-layer wafer to form a semiconductor. The method includes implanting ions throughout select portions of an epitaxial layer that are to be removed through etching. The ion implantation weakens the molecular structure of the implanted portions of the epitaxial layer and increases the vulnerability of the implanted portions to select liquid etchants or etching solutions. As such, the etching process has less impact on those portions of the epitaxial layer that were not subjected to ion implantation.

### FIELD OF THE INVENTION

The present invention relates to semiconductor processing, and in particular, to an efficient and effective etching process.

### BACKGROUND OF THE INVENTION

When creating a semiconductor, numerous epitaxial layers are grown or deposited on a base wafer. Depending on the type of semiconductor being produced, each epitaxial layer will have a certain chemical make-up, wherein atoms from various doping materials have been diffused or otherwise forced into one or more of the epitaxial layers to affect the epitaxial layer's ability to conduct electricity. In essence, the dopant atoms displace some of the wafer's original atoms to make the wafer either more or less conductive. Doping typically occurs during the manufacture of the wafer by exposing the epitaxial layers as they are created to various chemicals, or by using ion implantation. Ion implantation is a process that bombards all or a portion of the epitaxial layers with charged atoms, called ions, to displace the select atoms. Thus, a wafer having various epitaxial layers of varying chemical-electrical makeup is produced.

In order to create electrical components within the epitaxial layers and on the wafer, sections of the epitaxial layers must be removed in varying numbers and degrees about each component. Typically, a process referred to as photolithography is used to create a light-sensitive photoresist over the exposed epitaxial layer or layers. Light is then shone through a mask representing the surface area of the epitaxial layer(s) to remain and to ultimately form a portion of the desired circuit or circuitry. Exposure to light causes the photoresist to resist certain chemicals, which are then applied to remove the photoresist that was not exposed. At this point, a photoresist corresponding to a desired portion of the circuit or circuitry remains on the surface of the exposed epitaxial layers.

In order to remove all or certain epitaxial layers that are not under the remaining photoresist, the uncovered regions are exposed to chemical etchants. Some chemical etchants selectively attack and remove only desired materials. Thus, the etching process automatically stops once the desired material has been removed, rather than continuing all the way through each of the various epitaxial layers. Unfortunately, chemical etching is an isotropic process, wherein the etching occurs in all directions and not just vertically under the remaining photoresist. In many cases, the etching will essentially undercut the remaining photoresist. The amount of undercut is often difficult to control, and always affects the electrical characteristics of the devices being formed. The extent of etching is often difficult to control, because its rates are affected by: the temperature, humidity, strength, and concentration of the etching solutions; the morphology and cleanliness of the surface being etched; and the various orientations of crystalline substrates. In addition to isotropic etching, it is often also difficult to control the depth to which etching occurs.

The inability to strictly control etching results in undesirable consequences in the structure and characteristics of the resulting components. Most often, the resulting components have a slightly different design than originally anticipated, resulting in the component having different electrical characteristics than originally anticipated. In order to control etching and provide high pattern fidelity and edge definition, cost- and process-intensive techniques need to be employed. For example, extreme temperatures or controlled humidity chambers are often necessary to etch some materials, thereby resulting in increased manufacturing and facility costs, and increased risk for potential defects in the semiconductors if the conditions are not precisely maintained.

An example of a particularly difficult structure for etching is a common heterojunction bipolar transistor (HBT) substrate system wherein a gallium arsenide (GaAs) base epitaxial layer supports an indium gallium phosphide (InGaP) emitter epitaxial layer. The InGaP emitter epitaxial layer only etches in concentrated hydrochloric acid (HCl) and does not etch in the traditional etchants used for GaAs epitaxial layers. Likewise, the hydrochloric acid does not attack the GaAs epitaxial layers. Thus for GaAs/InGaP systems, a traditional GaAs etchant must be used after the HCl etch.

Etching with concentrated HCl, however, has proven difficult to control. Due to the reactive nature of the concentrated acid, the etch rate is high, and often results in poor pattern transfer and poor edge acuity through the InGaP emitter epitaxial layer. Thereafter, the low degree of pattern fidelity is maintained because the pattern etched within the InGaP epitaxial emitter layer is transferred to the underlying GaAs base and collector epitaxial layers during the remainder of the etching process.

As such, there is a need for an accurate and efficient etching technique to overcome the difficulties imposed by the prior art etching techniques.

### SUMMARY OF THE INVENTION

The present invention is an improved method for etching away portions of epitaxial layers in a multi-layer wafer to form a semiconductor. The method includes implanting ions throughout select portions of an epitaxial layer that are to be removed through etching. The ion implantation weakens the molecular structure of the implanted portions of the epitaxial layer and increases the vulnerability of the implanted portions to select liquid etchants or etching solutions. As such, the etching process has less impact on those portions of the epitaxial layer that were not subjected to ion implantation.

Preferably, a photoresist pattern is applied over a surface of the first epitaxial layer to form a masked and an unmasked portion of the first epitaxial layer wherein only the unmasked portion of the first epitaxial layer is implanted with ions during the ion-implanting step. The ions are typically implanted throughout the unmasked portion of the epitaxial layer such that the entire unmasked portion of the epitaxial layer is removed during etching. To maintain pattern fidelity corresponding to the photoresist pattern, the portion of the epitaxial layer implanted with ions is defined by a boundary substantially perpendicular to the epitaxial layer about the masked portion. After etching, the photoresist pattern applied to the epitaxial layer is removed.

Multiple etching steps may be required to create semiconductor components with the multi-layer structure of the wafer. The subsequent etching steps may or may not incorporate ion implantation. If ion implantation is not incorporated, a second epitaxial layer may be exposed to a second etching solution configured to remove the second epitaxial layer. Preferably, the second etching solution is different than the etching solution used to remove the ion implanted portions of the first epitaxial layer.

Those skilled in the art will appreciate the scope of the present invention and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the invention, and together with the description serve to explain the principles of the invention.

FIG. 1 illustrates a wafer having multiple epitaxial layers and with photoresist applied on select portions of the wafer.

FIG. 2 illustrates an etched wafer having deficiencies from processing using techniques of the prior art.

FIG. 3 illustrates a wafer having a first epitaxial layer implanted with ions in areas not covered by the photoresist.

FIG. 4 illustrates the wafer of FIG. 3 etched to remove the portions of the epitaxial layer subjected to ion implantation.

FIG. 5 illustrates the wafer fully etched according to one embodiment of the present invention.

### DETAILED DESCRIPTION OF THE PREFERRED EMBODIMENTS

The embodiments set forth below represent the necessary information to enable those skilled in the art to practice the invention and illustrate the best mode of practicing the invention. Upon reading the following description in light of the accompanying drawing figures, those skilled in the art will understand the concepts of the invention and will recognize applications of these concepts not particularly addressed herein. It should be understood that these concepts and applications fall within the scope of the disclosure and the accompanying claims.

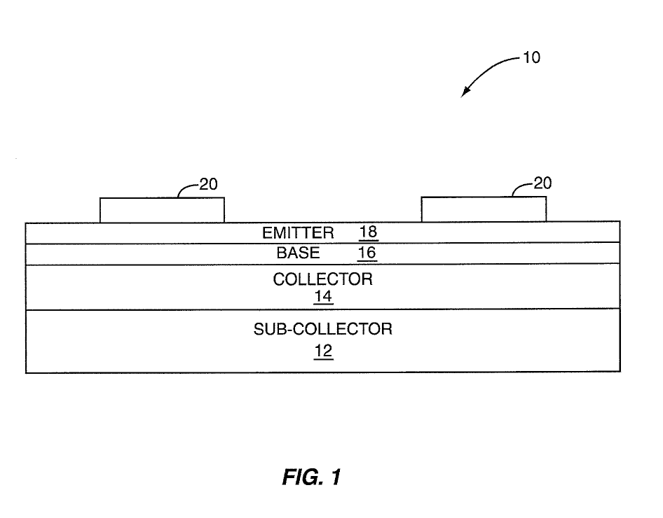

The present invention is described below in conjunction with a specific heterojunction bipolar transistor (HBT) process employed by RF Micro Devices of Greensboro, N.C.; however, those skilled in the art will understand the applicability of the present invention to other materials and semiconductor forms. FIG. 1 illustrates a wafer 10 including a plurality of epitaxial layers 12-18 prior to etching. In one embodiment, the wafer is formed with the following epitaxial layers: a Gallium Arsenide (GaAs) sub-collector epitaxial layer 12; a GaAs collector epitaxial layer 14; a GaAs base epitaxial layer 16; and an Indium Gallium Phosphide (InGaP) emitter epitaxial layer 18.

In order to create electrical components within the epitaxial layers 12-18 of the wafer, sections of the epitaxial layers 12-18 must be removed about each component. A process referred to as photolithography may be used to create a light-sensitive photoresist over the exposed epitaxial layer(s) 12-18. Light is then shone through a mask representing the surface area of the epitaxial layer to remain and ultimately form a portion of the desired circuit or circuitry. Exposure to light causes the photoresist to resist certain chemicals, which are applied to remove the photoresist that was not exposed. At this point, a photoresist corresponding to a desired portion of the circuit or circuitry remains on the surface of the exposed epitaxial layers. As illustrated in FIG. 1, two sections of photoresist 20 are shown to remain on the emmiter epitaxial layer 18.

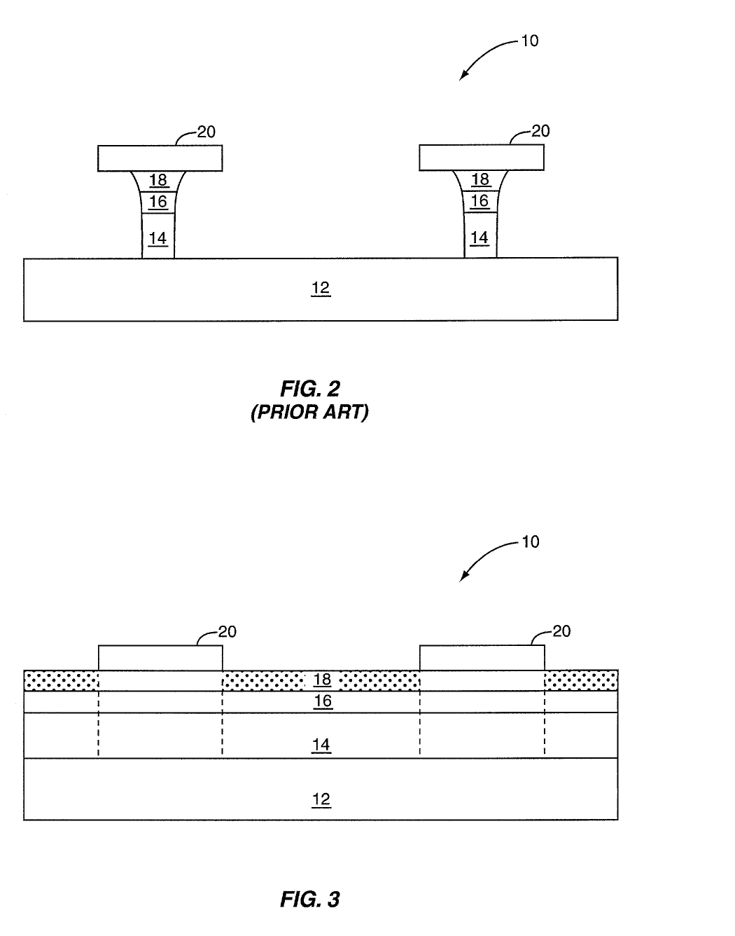

In order to remove all or certain epitaxial layers that are not under the remaining photoresist, the uncovered regions are then exposed to chemical etchants. The chemical etchants selectively attack and remove only desired materials. Thus, the etching process theoretically stops once the desired material has been removed, rather than continuing all the way through each of the various epitaxial layers 12-18. As noted, chemical etching is an isotropic process, wherein the etching occurs in all directions and not just vertically under the remaining photoresist 20. In many cases, the etching will essentially undercut the remaining photoresist 20 as illustrated in FIG. 2. Such undercutting often results in further undercutting in subsequent etching processes for lower epitaxial layers, resulting in dramatic differences from the theoretical design. The amount of undercut is often difficult to control, and always affects the electrical characteristics of the devices being formed.

In order to minimize the effects of undercutting during etching, the present invention essentially modifies the chemical makeup of one or more epitaxial layers being etched to allow for more controllable etching. Preferably, portions of an epitaxial layer not covered by the photoresist 20 are modified, wherein the modified portions of the epitaxial layer respond to select etching chemicals more readily than unmodified portions of the epitaxial layer. In one embodiment, portions of the epitaxial layer being etched are implanted with ions, wherein the implanted portions of the epitaxial layer are more responsive to the etching chemicals. Preferably, upon application of the patterned photoresist 20, the epitaxial layer to be etched is subjected to ion implantation wherein the patterned photoresist 20 shelters from ion implantation portions of the epitaxial layer intended to remain after etching.

Although ion implantation has been used for other purposes, heretofore ion implantation has not been appreciated for assisting etching processes. For example, ion implantation has been used for purposes of doping, where the wafer is exposed to ion-implanted impurities to selectively modify the electrical conductivity of the epitaxial layer. Ion implantation causes implantation damages to the crystal structure of the wafer material. Thus, in doping processes, the ion-implanted wafer is subsequently annealed to remove the created defects. Another use of ion implantation has been for forming trench isolation stops. For example, silicon wafers have been implanted with boron ions (B+) to provide specific trench profiles. Again, however, the boron-implanted silicon wafer is subjected to a rapid thermal annealing process.

Unlike in these techniques, the present invention does not require any subsequent annealing process. Rather, the present invention creates ion-implanted defects for the purpose of weakening the lattice structure of a particular epitaxial layer. Upon such weakening, the epitaxial layer is more easily etched in less extreme conditions. Thus, the epitaxial layer is etched more accurately. Epitaxial layers beneath the implanted epitaxial layer may then be etched more accurately as well.

An example of the invention process is illustrated in association with FIGS. 3, 4, and 5. Upon applying patterned photoresist 20, ions are implanted within the InGaP emitter epitaxial layer 18 that is not covered by the patterned photoresist 20 as shown in FIG. 3. The photoresist mask 20 protects the pattern from the ion implantation. The ion-implanted portions of the emitter epitaxial layer 18 are illustrated with shading. Preferably, singly ionized argon (Ar+) is used as the implanted ion. Argon is preferred because it is relatively heavy, and therefore causes more damage to the epitaxial layer using a lower dose, and because it is chemically inert to the system. Other ionizable elements that achieve the results of the present invention should be considered within the scope of this disclosure and the appended claims.

Preferably, the argon is ionized in a vacuum chamber, accelerated, and imbedded within wafer 10 with an implanter, as is known in the art. The argon dosage preferably is greater than 1×10¹⁴ ions/cm². As is known in the art, the concentration is controlled by the implantation current. Further, preferably, the tilt angle is between about 6.8° and 7.2°, most preferably about 7°. Preferably, the twist angle is between about 44° and 46°, most preferably about 45°.

By manipulating the acceleration voltage, implantation depth can be precisely controlled. Thus, the thickness of the InGaP emitter epitaxial layer 18 will dictate the acceleration energy to be used. This calculation is within the skill of those in the art. For example, for an InGaP emitter epitaxial layer 18 of about 500 Å thick, the acceleration energy preferred is about 100 Kilo-electric volts (KeV).

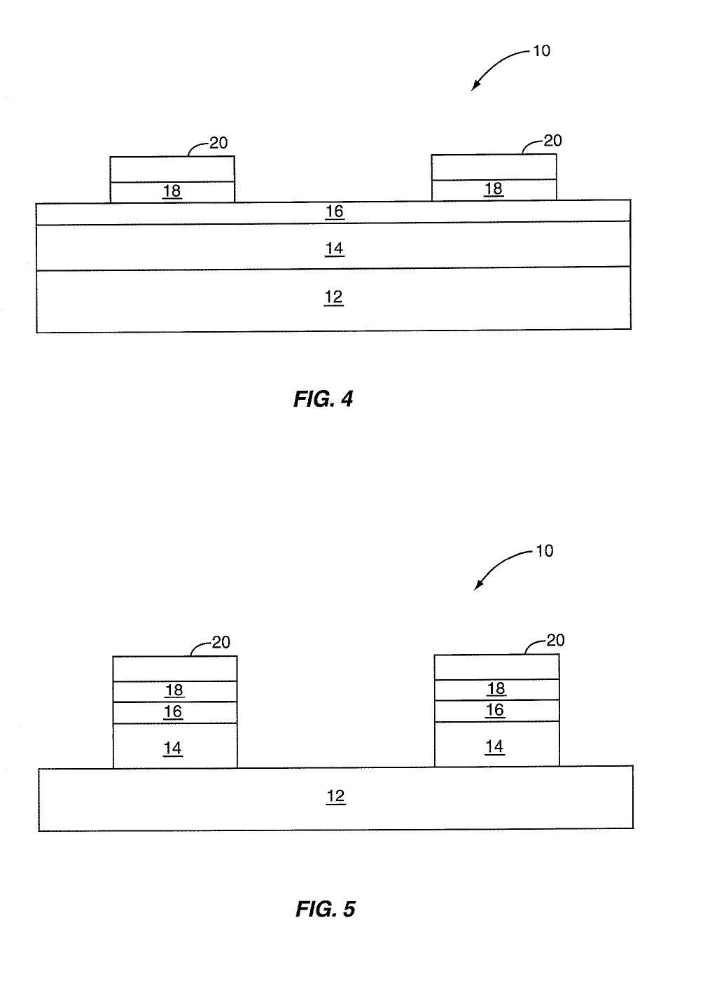

After implantation, the InGaP emitter epitaxial layer 18 is substantially weaker and etchable using a liquid etchant, which is typically in a lower acid concentration solution than required for etching non-implanted portions. Preferably, the implanted portions of the emitter epitaxial layer 18 are etched with a solution that is, by volume, two parts water and one part 30% HCl solution. Thus, the preferred solution is effectively a 10% HCl solution. Unlike the concentrated HCl solutions that were heretofore necessary to etch InGaP epitaxial layers, the present invention allows a 10% HCl solution that is more controllable to effectuate a high degree of pattern fidelity and good edge acuity as illustrated in FIG. 4. The weakly concentrated HCl solution does not etch the non-implanted portions of the InGaP emitter epitaxial layer 18. Thus, the present invention provides the desired anisotropic effect.

Thereafter, the GaAs collector and base epitaxial layers 14, 16 are removed by being subjected to typical GaAs etchants, such as an ammonia solution, as show in FIG. 5. Optionally, if overhang of InGaP emitter epitaxial layer 18 exists after the GaAs collector and base epitaxial layers 14,16 are etched, the InGaP emitter epitaxial layer 18 can be etched with a slightly more concentrated HCl solution, such as 3 parts 30% HCl in water and 1 part water, thus, 15% HCl by volume in water, to remove the overhang. Maintaining a vertical etching characteristic through the InGap emitter epitaxial layer 18 during the initial etching process allows more precise control of subsequent etching processes for removing the GaAs collector epitaxial layer 14 or the GaAs base epitaxial layer 16. Notably, the subsequent etching processes may or may not incorporate ion implantation to facilitate greater etching control. Finally, the wafer 10 may be subjected to any typical remaining processing steps as are known in the art, such as stripping of the photoresist pattern 20. In the illustrated example, emitter mesas are formed in a GaAs process having substantially more vertical walls than previously attainable.

Although specific embodiments of the present invention have been illustrated and described in detail, it is to be expressly understood that the invention is not limited thereto. The above detailed description of the embodiment is provided for example only and should not be construed as constituting any limitation of the invention. Thus, modifications will be obvious to those skilled in the art, and all modifications that do not depart from the spirit of the invention are intended to be included within the scope of the appended claims.

What is claimed is:

1. A method for semiconductor etching comprising:
a) implanting ions in a portion of a first epitaxial layer to be removed; and
b) subjecting the first epitaxial layer to a first etching solution configured to remove the portion of the first epitaxial layer implanted with ions,
wherein the portion of the first epitaxial layer implanted with ions is removed by the first etching solution without significantly impacting a portion of the first epitaxial layer not implanted with ions.

2. The method of claim 1 further comprising applying a photoresist pattern over a surface of the first epitaxial layer to form a masked and an unmasked portion of the first epitaxial layer wherein only the unmasked portion of the first epitaxial layer is implanted with ions during the implanting step.

3. The method of claim 2 wherein the ions are implanted throughout the unmasked portion of the first epitaxial layer such that all of the unmasked portion of the first epitaxial layer is removed during etching.

4. The method of claim 3 wherein the portion of the first epitaxial layer implanted with ions is defined by a boundary substantially perpendicular to the first epitaxial layer about the masked portion of the first epitaxial layer such that etching results in enhanced pattern fidelity beneath the masked portion of the first epitaxial layer.

5. The method of claim 2 further comprising removing the photoresist pattern from the masked portion of the first epitaxial layer after the subjecting step.

6. The method of claim 1 further comprising subjecting a portion of a second epitaxial layer exposed by the etching of the first epitaxial layer to a second etching solution configured to remove the second epitaxial layer.

7. The method of claim 6 wherein the first etching solution is different that the second etching solution.

8. The method of claim 7 wherein the first epitaxial layer comprises Indium Gallium Phosphide and the second epitaxial layer comprises Gallium Arsenide.

9. The method of claim 7 wherein the first etching solution is a hydrochloric acid solution and the second etching solution is an ammonia solution.

10. The method of claim 1 wherein the implanted ions are singly ionized argon.

11. The method of claim 1 wherein the first epitaxial layer comprises Indium Gallium Phosphide.

12. The method of claim 1 wherein the first etching solution is a hydrochloric acid solution.

13. A method for forming a compound semiconductor comprising:
a) providing a wafer having a first epitaxial layer of a first material above a second epitaxial layer of a second material;
b) photolithographically applying a photoresist pattern over a surface of the first epitaxial layer to form a masked and an unmasked portion of the first epitaxial layer;
c) implanting ions throughout the unmasked portion of the first epitaxial layer;
d) subjecting the first epitaxial layer to a first liquid etchant, which is unable to etch the second material;
e) subjecting the second epitaxial layer a second liquid etchant, the second liquid etchant being unable to etch the first material; and
f) removing the photoresist from the masked portion of the first epitaxial layer that remains.

14. The method of claim 13 further comprising subjecting the first epitaxial layer to a liquid etchant after the second epitaxial layer has been etched to eliminate any overhang of first epitaxial layer after etching.

15. The method of claim 14 wherein the liquid etchant applied to the overhang is approximately 15% hydrochloric acid by volume in water.

16. The method of claim 13 wherein the compound semiconductor is an Indium Gallium Phosphide/Gallium Arsenide heterojunction bipolar transistor and the first epitaxial layer is comprised of Indium Gallium Phosphide and the second epitaxial layer is Gallium Arsenide.

17. The method of claim 13 wherein the first liquid etchant is a hydrochloric acid solution and the second liquid etchant is an ammonia solution.

18. The method of claim 13 wherein the implanted ions are singly ionized argon.

19. The method of claim 13 wherein the first etching solution is an hydrochloric acid solution.

20. A method for semiconductor etching comprising:
a) implanting ions throughout a select portion of an epitaxial layer and substantially perpendicular to a surface of the epitaxial layer; and
b) etching away the select portion of the first epitaxial layer with an etching solution configured to remove the select portion of the epitaxial layer,
wherein the select portion of the epitaxial layer is removed by the etching solution without significantly impacting portions of the epitaxial layer not implanted with ions to provide high pattern fidelity after etching.

21. The method of claim 20 further comprising applying a photoresist pattern over an exposed surface of the epitaxial layer to define a masked portion and the select portion of the epitaxial layer wherein only the select portion of the epitaxial layer is implanted with ions during the implanting step.

22. The method of claim 21 further comprising removing the photoresist pattern from the masked portion of the epitaxial layer after the etching step.
